(19) United States
(12) Patent Application Publication
(10) Pub. No.: US 2022/0418143 A1
(43) Pub. Date: Dec. 29, 2022

(54) SYMMETRICAL WALL-MOUNTED 2-PIECE CABINET FOR COMPUTER NETWORK EQUIPMENT

(71) Applicant: Cheval Electronic Enclosure Company Limited, Samut Prakan (TH)

(72) Inventor: Apichart SAJCHWONG, Samut Prakan (TH)

(73) Assignee: Cheval Electronic Enclosure Company Limited, Samut Prakan (TH)

(21) Appl. No.: 16/765,458

(22) PCT Filed: Mar. 20, 2020
(86) PCT No.: PCT/TH2020/000013

§ 371 Date: May 19, 2020

(30) Foreign Application Priority Data
Jan. 31, 2020 (TH) 2001000633

(51) Int. Cl. H05K 7/14; H05K 5/02

(52) U.S. Cl. CPC H05K 7/1488; H05K 5/0226

(57) ABSTRACT

A symmetrical wall-mounted 2-piece cabinet for computer network equipment and in-building communication that can rotate for opening on the left or right by the same mechanism without having to change the pivot point is composed of a front piece functioning as the cabinet for holding computer network equipment, where the front piece of the cabinet has a door that can be opened or closed in accessing equipment from the front, and a back piece in the form of a robust structure functioning to attach the entire structure of the cabinet to the building wall. The invention helps the operator to turn the front piece of the cabinet using the operator's own strength, and reduces limitations in the installation of a cabinet in a wall-mounted fashion in a narrow space or building corner, while also enhancing usage safety and maintaining structural weight balance, which increases the usage life of the wall-mounted cabinet.

### BRANCH OF SCIENCE ASSOCIATED WITH THE INVENTION

Engineering in the parts concerned with wall-mounted 2-piece cabinets for computer network equipment and in-building communication designed with only one pivot mechanism causing symmetrical weight bearing with the ability to open to the left or right by the same mechanism without having to change the pivot point.

### BACKGROUND OF RELATED ART OR SCIENCE

The use of computer networks requires equipment to connect different computers together to form a network covering the entire usage area. All of the equipment is to be installed inside a wall-mounted cabinet. It often holds network equipment in the form of network security protection equipment. The equipment meets the IEC 297 standard, which specifies a width of 19 inches.

FIG. 1 illustrates a cabinet in the early days. It is a single wall-mounted cabinet with a door for opening and closing in its front. It contains posts for installing 19-inch equipment on the left and on the right in the front of the cabinet. The back contains a panel for mounting to the wall of a building and an opening for signal cables to exit as they run through the cable rails inside the building. A problem with this design is that, while working, the rear of the installed equipment often contains a large number of signal cables, so it becomes necessary to remove the equipment before work, and then the equipment has to be reconnected in its place. This creates difficulties, wastes time and might cause accidents.

FIG. 2 illustrates the current cabinet design available in the market. It is a 2-piece, 19-inch, wall-mounted cabinet divided into the front piece functioning in equipment installation and the back piece functioning in wall mounting. This type of cabinet can be opened where the front and back pieces can be separated from each other to facilitate access to network equipment installed to the front piece. At the same time, it allows the opening of the front door for viewing light indicators or accessing the network equipment from the front and back at the same time. The back piece functions to attach the entire cabinet to the building wall as well as store signal cables or electrical cables for later use, including other small equipment.

However, this cabinet design also has a flaw in that the hinges serve as both the pivots and connection points between the front and back pieces while also functioning to support the entire weight of the cabinet. As a result, when the cabinet is opened for use, and the front piece is separated from the back piece, the front piece falls and imbalance occurs, and if the operator needs to change the pivot in opening the front piece of the cabinet to a different side, it becomes necessary to remove the hinges in order to do so, which becomes a complication and wastes time.

In addition, the above cabinet requires a wide side installation space to permit the opening of the front piece for use, so the cabinet cannot be installed in limited spaces or narrow building corners.

The 19-inch wall-mounted 2-piece cabinet is disclosed in U.S. Pat. No. 6,755,493B1 for “wall-mounted cabinet having improved hinge design”. Improvements were made such that the structure for the installation of the cabinet and hinges are modified to become shafts for attaching to the structure of the back piece to improve hinge strength. As a result, the front piece of the cabinet can support more weight, and it is more convenient to remove-assemble hinges in order to change the pivot to another side.

FIG. 3 references Petty Patent Application No. 1703001781 for a 19-inch wall-mounted 2-piece cabinet with a base to support weight for the installation of 19-inch equipment. This 2-piece wall-mounted cabinet is special in that the back piece has a base which protrudes from the underneath to support the entire weight of the front piece, and the hinges only function as the pivots for opening the front piece to either the left or the right, so the problem of the front piece falling is resolved. However, it still has a disadvantage in regards to the assembly and disassembly of new hinges in cases where the operator has to change the pivots for opening the front piece from one direction to another, and it also has a limitation in regards to the side installation area whereby it cannot be installed in limited spaces or narrow building corners.

### Invention Characteristics and Objectives

This invention is related to the wall-mounted 2-piece cabinet designed where the structure of the back piece has upper and lower arms protruding from the structure at right angles with the structure of the back piece to facilitate installation of the pivot mechanism and assembly of the front and back pieces together instead of by using hinges. In addition, the upper and lower arms also serve to support the weight of the cabinet when it is turned and opened for use at the back of the front piece to ensure that weight is balanced in both structures.

This invention is designed with a mechanism for allowing the front piece to slide in and out of the back piece conveniently. When the front piece is slid out, it will be possible to turn the front piece either to the left or to the right without having to change the pivots. As a result, this 19-inch wall-mounted cabinet has less usage space requirements than 19-inch wall-mounted cabinets in current use. In addition, it also has a mechanism for adjusting the upper and lower arms to balance the weight support, which strengthens and increases the weight support of the cabinet.

### BRIEF DESCRIPTION OF DRAWING

FIG. 1 shows the installation characteristics and usage of a one-piece wall-mounted cabinet for computer and communication network equipment inside a building.

FIG. 2 shows the nature of use and installation limitations of a 19-inch 2-piece wall-mounted cabinet where the front piece functions in equipment installation and the back piece functions in wall-mounting.

FIG. 3 shows a 19-inch 2-piece wall-mounted cabinet with a base set for supporting the installation of 19-inch equipment.

FIG. 4 shows the 19-inch symmetrical wall-mounted 2-piece cabinet for computer network equipment and in-building communication that can rotate for opening on the left or right by the same mechanism without having to change the pivot point.

FIG. 5 shows the opening of the 19-inch symmetrical wall-mounted 2-piece cabinet for computer network equipment and in-building communication that can rotate for opening on the left or right by the same mechanism without having to change the pivot point, which can rotate for use while the front door is open.

FIG. 6 shows the front piece of the 19-inch 2-piece symmetrical wall-mounted cabinet.

FIG. 7 shows the back piece of the 19-inch 2-piece symmetrical wall-mounted cabinet.

FIG. 8 shows the structure of the back piece of the 19-inch 2-piece symmetrical wall-mounted cabinet.

FIG. 9 shows the lower base and lower arm of the back piece of the 19-inch 2-piece symmetrical wall-mounted cabinet equipped with the lower pivot mechanism set.

FIG. 10 shows the details of the lower pivot mechanism set of the 19-inch 2-piece symmetrical wall-mounted cabinet.

FIG. 11 shows the upper base and upper arm of the back piece of the 19-inch 2-piece symmetrical wall-mounted cabinet equipped with the upper pivot mechanism set.

FIG. 12 shows the details of the upper pivot mechanism set of the 19-inch 2-piece symmetrical wall-mounted cabinet.

FIG. 13 shows the assembly and installation of the front and back of the 19-inch symmetrical wall-mounted 2-piece cabinet for computer network equipment and in-building communication that can rotate for opening on the left or right by the same mechanism without having to change the pivot point.

FIG. 14 shows the assembly of the screws with the lower mechanism set.

FIG. 15 shows the assembly of the screws with the upper mechanism set.

FIG. 16 shows the installation and radius of the rotation of the 19-inch symmetrical wall-mounted 2-piece cabinet for computer network equipment and in-building communication that can rotate for opening on the left or right by the same mechanism without having to change the pivot point.

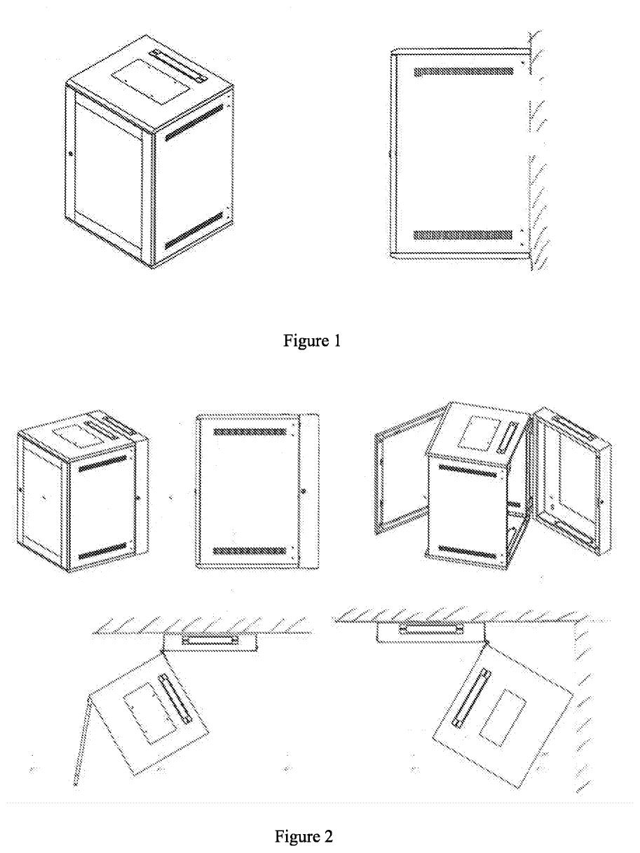

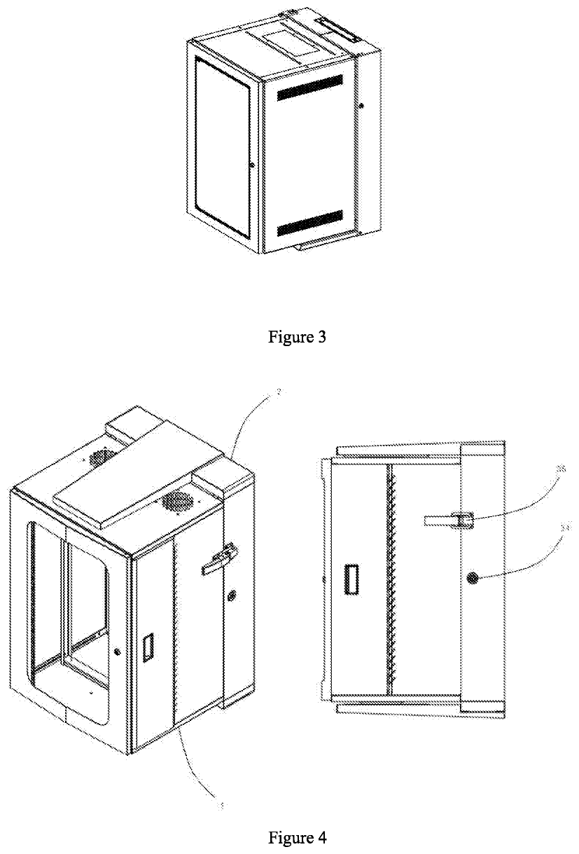

### FULL DISCLOSURE OF THE INVENTION

The 19-inch symmetrical wall-mounted 2-piece cabinet for computer network equipment and in-building communication that can rotate for opening on the left or right by the same mechanism without having to change the pivot point designed in this invention discloses the description of the invention as shown in the following figures:

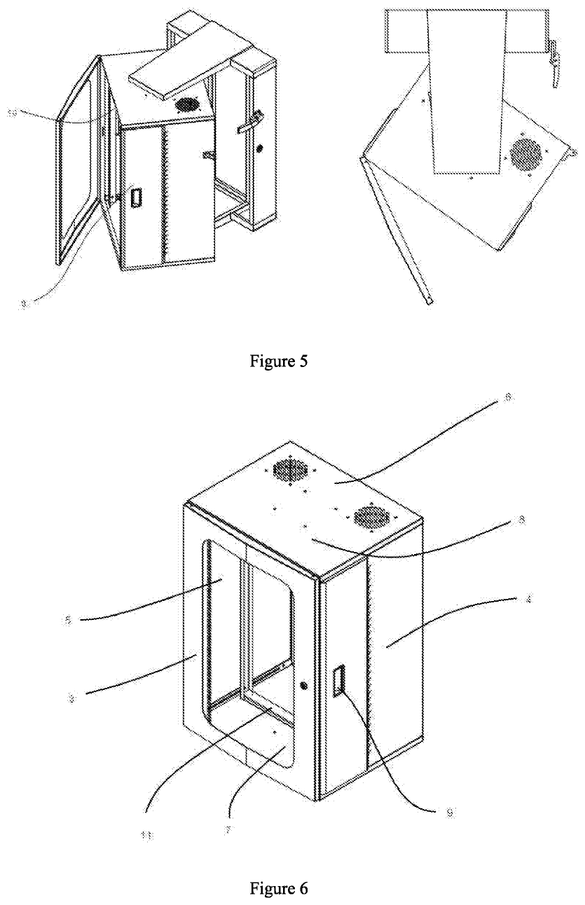

FIGS. 4 and 5 show the 19-inch 2-piece symmetrical wall-mounted cabinet capable of being opened by turning to the left or right in a single mechanism without having to change the pivots. It is composed of two pieces, namely, the front piece of the cabinet (1) functioning as the part of the cabinet for holding the computer network equipment, where the front piece of the cabinet has a door for opening and closing in accessing the equipment from the front; and the back piece of the cabinet (2) as a robust structure functioning to hold the entire structure of the 19-inch cabinet to the building wall. Upper-lower arms function as connection and pivot points so that the front piece of the cabinet (1) can be opened to either the left or the right.

FIG. 6 shows the front piece of the cabinet (1). It is composed of the front door (3), right side cover (4), left side cover (5), upper cover (6) and lower cover (7), which form the external structure of the front piece for both attractiveness and safety protection in regards to access to the installed network equipment. The right side cover (4) and the left side cover (5) are equipped with the right handle (9) and the left handle (10) to permit holding while pulling the front piece either inside or out along the length of the back piece while serving as holding positions for while turning the front piece of the cabinet (1) open. The front piece of the cabinet (1) functions in the installation of computer and communication network equipment. The front piece of the cabinet (1) also contains equipment installation posts on the inside. The rear of the front piece consists of an open panel for convenience in network equipment installation and maintenance (not shown), and the inside of the front piece of the cabinet (1) is a rectangular frame (11) assembled at the middle; it is a structure that reinforces the strength of the front piece of the cabinet (1) in order to help maintain its shape and provide better weight support. It is apparent that the front piece of the cabinet (1) at the top and bottom contains points for installation for assembly with the back piece (8) at opposing positions for use in assembling with the back piece to create a bi-directional turning mechanism.

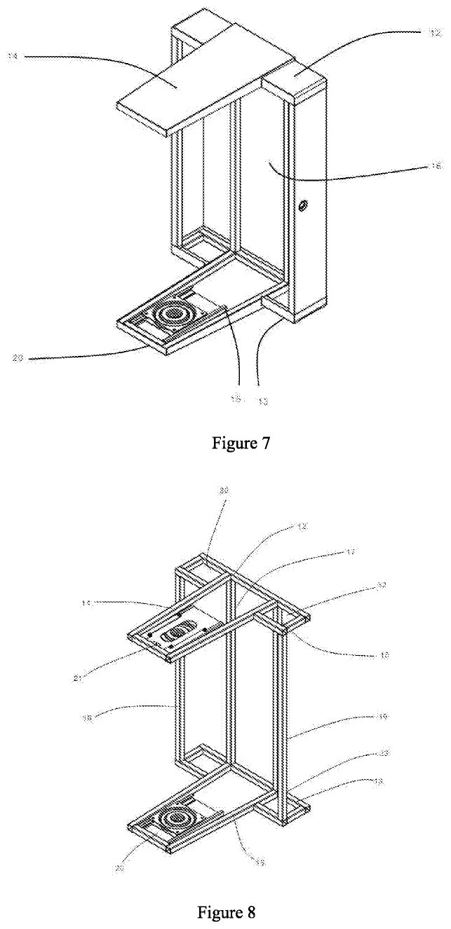

FIG. 7 shows the back piece of the cabinet as a structure composed of the upper base (12) and lower base (13) with an upper arm (14) and a lower arm (15) that protrude in right angles to the structure of the back piece in a parallel line. The lower part of the structure (16) functions to create space for attaching to the building wall. The upper arm (14) and the lower arm (15) have rails for installing the mechanism set for use in connecting the front piece instead of using hinges and that provide the mechanism for sliding the front piece in and out for when turning the front piece open to the left or the right.

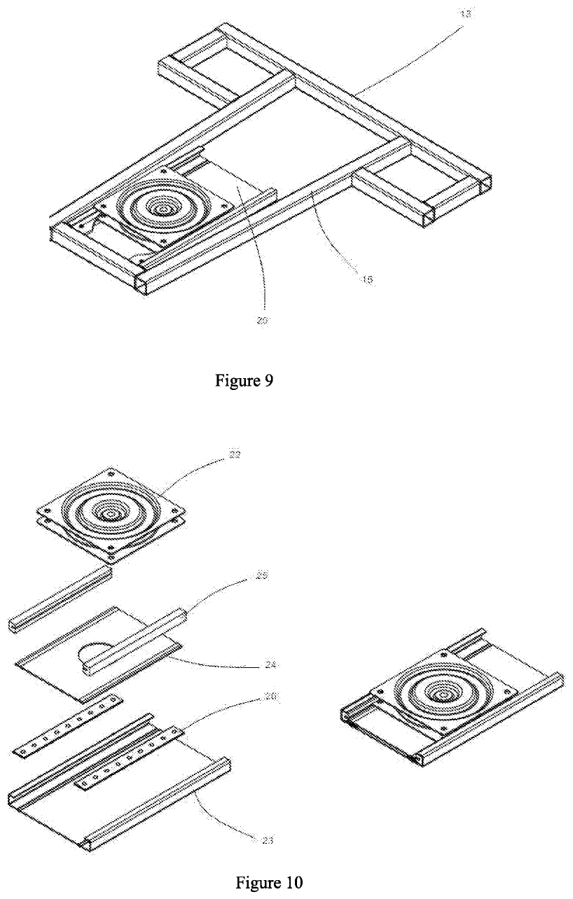

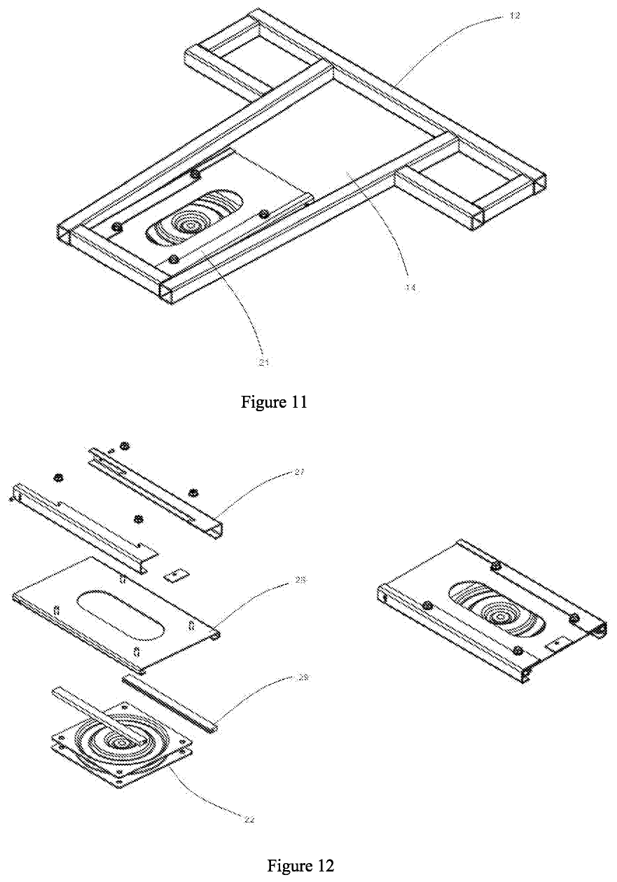

FIG. 8 shows the structure of the back piece of the cabinet that was designed to structures connected together for added strength. The upper base (12) and lower base (13) are symmetrical, positioned opposite to each other and connected by four rear structure posts (16) (17) (18) (19), which are strong and maintain their shape. The inner left post (17) has an upper corner and bottom corner with an upper join (30) and lower join (31) connected at each corner. In the same positions for the right-hand post (18) are also an upper join (32) and a lower join (33) connected at each corner. They function as points for wall mounting. The upper base (12) contains a structure called the upper arm (14) which protrudes in a right angle to the edge of the upper base (12). It is a rectangular structure which contains a space at the middle for the installation of the upper pivot mechanism (21), which attaches to the area as shown in FIG. 11. And at the lower base (13) is a structure called a lower arm (20) which has the same characteristics and structure as the upper arm (14), and it protrudes and composes the lower pivot mechanism (20) which is attached to the area as shown in FIG. 9.

The locking mechanism between the front piece of the cabinet (1) and the back piece of the cabinet (2) is designed for locking such that both pieces cannot be separated from each other by key (34), which is installed either on the left or the right side of the cabinet. It functions in locking the front piece of the cabinet (1) and the back piece of the cabinet (2) together, and it cannot be opened for pulling or turning for accessing the area at the back. It provides access security for equipment installed inside the 19-inch 2-piece wall-mounted cabinet.

And in locking to ensure that the front piece of the cabinet (1) and the back piece of the cabinet (2) are tightly connected to each other, the locking mechanisms of the right lock pin (35) and the left lock pin (not shown) are relied upon. They are installed on panels on both sides of the 19-inch 2-piece wall-mounted cabinet. The two locking mechanisms help ensure that the front piece of the cabinet (1) and the back piece of the cabinet (2) are more tightly connected to each other, which helps the structure of the cabinet in better supporting weight and bearing load when the locks of the front piece (1) and the back piece (2) join together.

FIG. 10 shows the lower pivot mechanism (19) composed of the bottom guide rail (22) connected to the lower arm (15). This guide rail is for guiding the direction of movement to either the front or the back of the front piece. The front or back movements are facilitated by the movements of bearings panel (26). The bearings panel is composed of an upper plate and a lower plate to keep the ball bearings inside spinning freely. The lower guide rail (23) and the bearings panel (26) are joined together independently. The left or right movements are facilitated by the bearings (22) assembled to the bottom guide plate (25). The bearings are attached to the bottom bearing installation plate (24), which when assembled to the lower guide rail (23) and bearings panel (26) produce the mechanism for enabling the front piece of the cabinet to move forward, backward, left and right.

FIG. 12 shows the upper pivot mechanism (21) functioning as the mechanism for guiding movement as follows. It is composed of left-right rail joint (27) assembled to the upper arm (14) functioning as the attachment for the upper guide rail (28). The rail functions in the forward and backward movements of the front piece. The upper guide rail (28) functions together with the upper guide rail support (29), and left and right movements are facilitated by bearings (22) that are assembled to the upper guide rail (28) assembled to the C-shaped grove in the left-right rail join (27). The assembly is independent of each other, and elevation can be adjusted to balance the weight support of the upper arm (14) and the lower arm (15) and to create a mechanism for directing the forward-backward movements and left-right rotations.

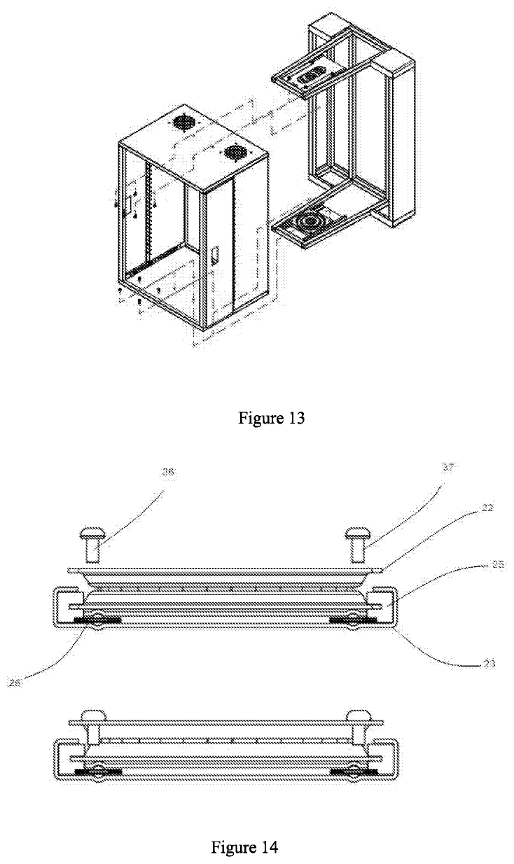

FIG. 13 shows the front piece (1) and the back piece of the cabinet (2) assembled together in the installation positions of the upper bearings and lower bearings. They are assembled using screws for attachments. In installing upper bearings, the distance between the front piece of the cabinet (1) and the back piece of the cabinet (2) creates balance in the weight bearing of the upper arm and the lower arm, whereby the balanced distribution of weight enhances the strength of the 19-inch 2-piece wall-mounted cabinet.

FIG. 14 shows details on the assembly of the front piece of the cabinet (1) and the back piece of the cabinet (2). In assembling them together, they are assembled such that the lower mechanism is fully attached first before the upper pivot mechanism set (21) is attached. In the assembly, it functions in the in and out movement of the front piece of the cabinet (1), and it serves as the pivot of the cabinet. Screw No. 1 (36) is used to attach the lower base of the front piece of the cabinet (1) to the bearings (22) assembled to the lower pivot mechanism (20).

Then Screw No. 2 (37) along with Screw No. 3 and 4 (not shown) are attached. When every screw is attached, they are tightened so that the lower base of the front piece of the cabinet (1) is tightly attached to the lower pivot mechanism set (20). If the screw is not sufficiently tight, the bearings panel (26) will not function in facilitating in the in-out movements of the front piece of the cabinet (1). Then the upper part of the front piece of the cabinet is assembled to the upper pivot mechanism set (21).

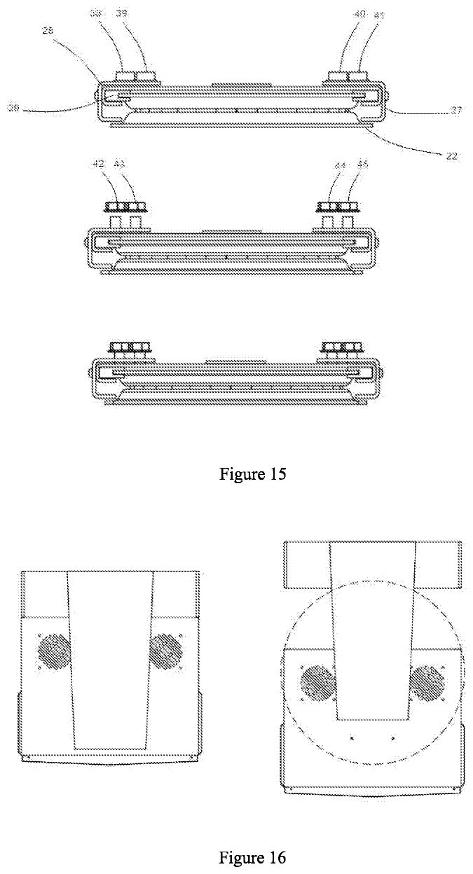

FIG. 15 shows details on the assembly of the front piece of the cabinet (1) and the back piece of the cabinet (2). They are assembled together according to the details for the installation of the upper pivot mechanism set (21) to tightly attach it to the back piece of the cabinet (2). In the assembly, they are attached, and the upper pivot mechanism set (21) functions in the in-out movement of the front piece of the cabinet (1) as well as serves as a pivot of the cabinet. Female Screw No. 1 (42) is attached to the screw pin position 1 (38). Female Screw No. 2 (43) is attached to screw pin position 2 (39). Female Screw No. 3 (44) is attached to Screw Pin Position No. 1 (40). And female Screw No. 4 (45) is attached to screw pin position 4 (41). In attaching the female screws to each position, they are tightened and levelled to cause the pivot mechanism set (21) to pull against the front piece of the cabinet (1), raising it up. Once the distance is adjusted by tightening, a gap will exist between the lower base of the attachment join rail (27) and the lower base of the upper guide rail (28). This gap is about 4-5 millimeters and is meant to allow both the upper and lower pivot mechanisms to function together and bear weight in a balanced manner.

FIG. 16 shows the distance of installation and the turning radius of the 19-inch 2-piece symmetrical wall-mounted cabinet. The operator can pull out the front piece to create more space for working in the back. Whenever turning the front cabinet to any direction is desired, as shown in the figure, the operator can turn the front piece by relying on the operator's own force. It is also apparent that the turning shown in this invention can reduce installation space limitations in wall corners while also helping to maintain balance and extending structure usage life.

Although certain exemplary embodiments and methods have been described in some detail, for clarity of understanding and by way of example, it will be apparent from the foregoing disclosure to those skilled in the art that variations, modifications, changes, and adaptations of such embodiments and methods may be made without departing from the true spirit and scope of the claims. Therefore, the above description should not be taken as limiting the scope of the invention.

The invention is not limited to the precise configuration described above. While the invention has been described as having a preferred design, it is understood that many changes, modifications, variations and other uses and applications of the subject invention will, however, become apparent to those skilled in the art without materially departing from the novel teachings and advantages of this invention after considering this specification together with the accompanying drawings. Accordingly, all such changes, modifications, variations and other uses and applications which do not depart from the spirit and scope of the invention are deemed to be covered by this invention as defined in the following claims and their legal equivalents. In the claims, means plus function clauses, if any, are intended to cover the structures described herein as performing the recited function and not only structural equivalents but also equivalent structures.

All of the patents, patent applications, and publications recited herein, and in the Declaration attached hereto, if any, are hereby incorporated by reference as if set forth in their entirety herein. All, or substantially all, the components disclosed in such patents may be used in the embodiments of the present invention, as well as equivalents thereof. The details in the patents, patent applications, and publications incorporated by reference herein may be considered to be incorporable at applicant's option, into the claims during prosecution as further limitations in the claims to patently distinguish any amended claims from any applied prior art.

1. A symmetrical wall-mounted 2-piece cabinet for computer network equipment and in-building communication comprising:
a front piece shaped like a box;
a back piece comprising an upper base and a lower base connected together in a perpendicular angle;
wherein connection of both parts becomes the back piece of the cabinet with posts in each corner;
an upper arm and a lower arm that extend along the same plane
wherein the upper arm and lower arm are positioned opposite from each other;
wherein the upper arm and lower arm are equipped with an upper pivot mechanism set and lower pivot mechanism set functioning as the connector between the front piece of the cabinet and the back piece of the cabinet;
and wherein said connector is configured to slide the front piece of the cabinet back and forth between the front and back within the distance of the upper arm and lower arm extending from both bases in order to handle the rotation of the front pieces of the cabinet to the left or right.

2. The symmetrical wall-mounted 2-piece cabinet for computer network equipment and in-building communication of claim 1 wherein:
the front piece of the cabinet has a structure comprising:
a front door;
a right side cover;
a left side cover;
an upper cover;
a lower cover;
wherein the right side panel and the left side panel have a right handle and the left handle installed;
wherein the rear of the front piece is an open panel
and wherein inside the front piece is a rectangular frame assembled at the middle.

3. The symmetrical wall-mounted 2-piece cabinet for computer network equipment and in-building communication of claim 1 further comprising space for installing equipment used as a mechanism for opening the door of the cabinet, wherein:
the back piece of the cabinet is structured in the shape of a “C”;
the structure of the upper base and the lower base extends from the middle of the position of both bases;
the structure extending outward is perpendicular;
wherein an upper arm and a lower arm are assembled opposite from and parallel to each other.

4. The symmetrical wall-mounted 2-piece cabinet for computer network equipment and in-building communication of claim 3 wherein:
the connection between the front piece of the cabinet and the back piece of the cabinet is achieved by a lower pivot mechanism assembled and installed at the lower arm
wherein said lower arm comprises of a lower guide rail;
wherein said guide rail comprises a bearings panel;
wherein said lower pivot mechanism comprises an upper and a lower plate;
wherein said lower guide rail and said bearings panel are assembled together independently; and
wherein said bearings are attached to the lower bearings installation plate.

5. The symmetrical wall-mounted 2-piece cabinet for computer network equipment and in-building communication of claim 4 wherein the lower pivot mechanism set comprising a bearings panel is designed with bearings arranged along the length of plates drilled for the bearings to assemble and rotate, and wherein said plates consist of an upper and lower plate.

6. The symmetrical wall-mounted 2-piece cabinet for computer network equipment and in-building communication of claim 4 wherein the lower pivot mechanism set is attached to the front piece of the cabinet by using nuts for functioning with the lower guide rail.

7. The symmetrical wall-mounted 2-piece cabinet for computer network equipment and in-building communication of claim 1 wherein lower pivot mechanism set in the function of the mechanisms of each work piece is assembled independently.

8. The symmetrical wall-mounted 2-piece cabinet for computer network equipment and in-building communication of claim 4 wherein the front piece of the cabinet and the back piece of the cabinet are assembled together by relying on the upper pivot mechanism assembled at the upper arm composed of the left-right joint assembled to the upper arm, and wherein the rail is used to facilitate moving position forward or backward of the front piece.

9. The symmetrical wall-mounted 2-piece cabinet for computer network equipment and in-building communication of claim 4 wherein the upper pivot mechanism set in the function of the mechanism set is assembled independently, and wherein if there are in-out movements in the forward or backward direction, movements will occur in the same direction for the left-right rail joint, upper guide rail, upper movement support and bearings.

10. The symmetrical wall-mounted 2-piece cabinet for computer network equipment and in-building communication of claim 1 wherein the assembly of the front piece of the cabinet and the back piece of the cabinet, upper pivot and lower pivot mechanisms are used together along with nuts and screws.

11. The symmetrical wall-mounted 2-piece cabinet for computer network equipment and in-building communication of claim 4 wherein assembling the front piece of the cabinet and the back piece of the cabinet together with the upper and lower pivot mechanisms will be used together along with nuts configured to permit adjustments of the space between the front piece and the back piece.

12. The symmetrical wall-mounted 2-piece cabinet for computer network equipment and in-building communication of claim 4 wherein the function of the lower arm relies on the function of the lower pivot mechanism assembled and installed at the lower arm, wherein the lower guide rail is attached to the lower arm and the bearings panel is composed of an upper plate and a lower plate.

13. The symmetrical wall-mounted 2-piece cabinet for computer network equipment and in-building communication of claim 4 wherein the function of the upper arm relies on the upper pivot mechanism assembled to the upper arm comprising the left-right join used to attach the upper guide rail.

14. The symmetrical wall-mounted 2-piece cabinet for computer network equipment and in-building communication of claim 4 wherein the front piece of the cabinet comprising the right side cover and the left side cover is installed with a right handle and a left handle.
